(19) United States
(12) Patent Application Publication
(10) Pub. No.: US 2021/0259116 A1
(43) Pub. Date: Aug. 19, 2021

(54) COUPLING SYSTEM AND METHOD FOR FLAT PANEL DISPLAYS

(71) Applicant: Grovist Innovations LLC, Las Vegas, NV (US)

(72) Inventor: Vince OVIST, Las Vegas, NV (US)

(21) Appl. No.: 16/714,234

(22) Filed: Dec. 13, 2019

Related U.S. Application Data
(63) Continuation of application No. 16/195,807, filed on Nov. 19, 2018, now abandoned.
(60) Provisional application No. 62/587,969, filed on Nov. 17, 2017.

(51) Int. Cl. H05K 5/00; F16B 12/20; H01R 13/436; A47G 1/16; F16M 11/00

(52) U.S. Cl. CPC H05K 5/0017; F16B 12/20; H01R 13/436; A47B 2097/005; A47G 1/1666; F16M 11/00; A47G 1/16

(57) ABSTRACT

A coupling system for flat panel displays includes a locking clip formed with a socket, a flat surface configuration, and is constructed to afford connection to a flat panel display from plural angles. There is also a suspension line, and the locking clip is formed with an internal cavity to assist in locking the suspension line in place once suspended.

### CROSS-REFERENCE TO RELATED APPLICATIONS

This application is a continuation of U.S. patent application Ser. No. 16/195,807, filed Nov. 19, 2018 and entitled “COUPLING SYSTEM AND METHOD FOR FLAT PANEL DISPLAYS”, which application claims priority to U.S. Provisional Patent Application Ser. No. 62/587,969, filed Nov. 17, 2017 and entitled “COUPLING SYSTEM AND METHOD FOR FLAT PANEL DISPLAYS”, the disclosure of which is herein incorporated by reference.

### BACKGROUND OF THE INVENTION

Conventional systems for mounting flat panel displays include the use of binder rings, fishing line, nuts and bolts, rigid pins with expanding grommet, and duct tape.

### SUMMARY OF THE INVENTION

The invention is a coupling system and method for flat panel displays. Referring to the Appendix, which shows three photographs of a version of the system invention, that system invention includes the following features:
1) Snap Socket Locking Clip in a flat configuration;
2) Plastic Construction;
3) Multiple connection angles.
4) Can be secured to any flat surface;
5) May be used in a cascading configuration, whereby each panel is supported by the panel above or, may be used in a suspension configuration whereby each panel is connected to a common line that bears the weight of all panels.
6) Uses an internal cavity to assist in locking the suspension line in place once suspended;
7) Ease of use;
8) Less labor required than with conventional systems;
9) Cleaner decorative lines than when using conventional systems;
10) May be paired and mated with “ball” plate Versaclips™ that are secured to a flat surface;
11) Easily Repaired; and
12) Retrofittable to conventional panel products.

The purpose of the invention is to allow the easy suspension of relatively lightweight elements such as flat panel displays or frames. Those elements may have a functional or decorative purpose, or a combination of both.

Conventional systems are cumbersome, unsightly, and unreliable. The system and method inventions solve all the problems encountered with the use of conventional systems by allowing users to suspend desired elements in an efficient and secure manner, while hiding from view, the coupling mechanism that enables the suspension.

By utilizing a ball chain or swaged ball cables, users can suspend elements in either a cascading arrangement, or in a more structural, substantially vertical arrangement which affords suspension of elements that have greater weight.

It is faster, safer, and stronger than conventional systems.

I claim:

1. A coupling system for flat panel displays, comprising:
a locking clip formed with a socket, and having a flat surface configuration, and constructed to afford connection to a flat panel display from plural angles;
a suspension line; and
wherein the locking clip is formed with an internal cavity to assist in locking the suspension line in place once suspended.
